(19) United States
(12) Patent Application Publication
(10) Pub. No.: US 2026/0098179 A1
(43) Pub. Date: Apr. 9, 2026

(54) A DIFFUSION COATING FOR A LIGHTING UNIT

(71) Applicant: Fotolec Technologies Limited, Thetford (GB)

(72) Inventors: Christopher Ian Wright, Thetford (GB); Christopher Leslie Payne, Thetford (GB)

(21) Appl. No.: 19/116,010

(22) PCT Filed: Sep. 26, 2023
(86) PCT No.: PCT/GB2023/052485

§ 371 Date: Mar. 27, 2025

(30) Foreign Application Priority Data
Sep. 29, 2022 (GB) 2214263.2

(51) Int. Cl. C09D 127/18; C08K 3/30; C09D 7/40; C09D 7/61; C09D 127/20; F21V 3/06; F21Y 115/10; H10H 29/85; H10H 29/855

(52) U.S. Cl. CPC C09D 127/18; C09D 7/61; C09D 7/67; C09D 7/68; C09D 7/69; C09D 127/20; F21V 3/0625; H10H 29/8506; H10H 29/855; C08K 2003/3045; C08K 2201/005; C08K 2201/011; F21Y 2115/10

(57) ABSTRACT

The disclosure relates to the coating of a Light Emitting Diode (LED) lighting tube or the like to diffuse and reduce spotting along with glare that is produced by the individual LEDs within the unit. More specifically, the disclosure relates to coating intended for use with LED light sources and for allowing the transmission of radiation in the ultra-violet (UV) range of 315 to 400 mm (UV-A), 280-315 mm (UV-B) and 100-280 nm (UV-C) wavelengths, also suitable for visible lights LEDs at 400 to 700 nm wavelengths.

This patent application is a U.S. National Phase filing of commonly owned and pending PCT Application No. PCT/GB2023/052485, filed Sep. 26, 2023, which is based on and claims the benefit of the filing date co-pending GB Patent Application Serial No. GB 2214263.2, filed Sep. 29, 2022, both which are incorporated herein by reference in their entirety.

### FIELD OF THE INVENTION

The present invention relates to the coating of a Light Emitting Diode (LED) lighting tube or the like to diffuse and reduce spotting along with glare that is produced by the individual LEDs within the unit. Spotting is caused by the spacing between the individual LEDs when placed on a board or strip. The coating is particularly intended for use with LED light sources and for allowing the transmission of radiation in the ultra-violet (UV) range of 315 to 400 nm (UV-A), 280-315 nm (UV-B) and 100-280 nm (UV-C) wavelengths, also suitable for visible lights LEDs at 400 to 700 nm wavelengths. A further benefit of the robust and versatile coating is that the lamps are protected from ingress from foreign bodies or contamination whilst all the internal components or fragments of such components are prevented from entering the environment in the case of unintentional breakage.

### BACKGROUND TO THE INVENTION

During the manufacture of traditional incandescent or fluorescent lighting units, in which the lighting unit has a transparent housing surrounding a light source—generating the light radiation—in the form of a bulb, tube or the like, a coating is often applied to one or both of the inner surface or the outer surface of the housing. The coating acts to reduce glare and to provide a more even light to the surroundings, as well as protect people in the vicinity of the light from UV-radiation emitted by the light source. A variety of materials is known for use as a coating depending on the material from which the housing is formed.

For example, in the case of glass housings, one method of forming a coating on the outside of a tube is to dissolve an acrylic monomer or resin in an organic solvent, optionally with transparent silicone particles suspended within. The solvent is then removed, with any necessary polymerisation taking place, to leave behind the coating. The disadvantage of using this method is that many of the most suitable solvents are toxic, and equipment needs to be in place to safely remove and capture the solvent removed. Alternatively, water-based systems can be utilised, but this often entails higher energy costs to remove the water compared to an organic solvent and also, frequently entails polymerisation of a monomer to form the coating.

In a similar solution to the above problems a pre-formed tube or film of material is secured about the housing. The material, such as a polyethylene terephthalate (PET), is provided as a preformed tube slid over the glass housing or is wrapped about the housing. The material can include a particulate material to aid in the diffusion of light to the user. One disadvantage of such a coating is that PET materials are susceptible to degradation by heat or UV-light. Under such conditions transmission by the coating can decrease and the coating can become brittle and flake leaving environment contamination along with a faulty lamp.

Prior art coatings typically have the aim also of filtering out any emitted radiation in the UV wavelengths as this can cause harm to people in the vicinity of the lighting unit. Often this is achieved by converting the ultra-violet (UV) radiation to radiation in the visible range (400 nm-700 nm) via fluorescence or phosphorescence. Even where coatings do allow for the transmission of UV-light, it is difficult to produce a coating which allows a specified wavelength or set of wavelengths to be transmitted (up to 60% drop-off in transmission of UV-A), or to control the thickness of the coating applied.

The present invention seeks to provide a coating which addresses the above problems and also enables a product to be produced which reduces the effect of ‘spotting’ in which scattering results in lighter or darker regions on the lamp, depending on where an LED lamp is located within the lighting unit. The coatings provided herein also act as a shatterproof coating or glass fragment retention coating which meets the requirements of IEC 61549 shatterproof safety lamps, required in food processing and associated industries standards to ensure a glass free environment, and where all glass fluorescent lamps must be shatterproof coated.

### SUMMARY OF THE INVENTION

According to a first aspect of the invention there is provided a lighting unit, the lighting unit comprising a light source retained within a housing, the housing having an outer coating comprising a polymeric material, the coating having distributed therein a particulate material to diffuse light emitted by the light source. The coating acts to diffuse and/or prevent transmission of light of pre-determined wavelengths and also to aid fragment retention and protection against ingress of water, insects and other materials harmful to the lighting unit. For example, the coating can be selected to allow transmission of UV between wavelengths 315 to 400 nm (UV-A), 280-315 nm (UV-B) and 100-280 nm (UV-C), also visible light between 400 nm-700 nm and also to act to diffuse the light radiation to provide a more even spread of emission in the vicinity of the lighting unit.

The polymeric material is preferably selected from a fluoropolymer such as polyvinylidene fluoride (PVDF), polychlorotrifluoroethylene (PCTFE), tetrafluoroethylene-ethylene copolymer (ETFE), tetrafluoroethylene-hexafluoropropylene copolymer (FEP), tetrafluoroethylene-perfluoroalkyl vinyl ether copolymer (PFA), polytetrafluoroethylene (PTFE), tetrafluoroethylene-hexafluoropropylene-vinylidene fluoride co-polymer (THV) and the like, and including mixtures thereof. Perfluorinated materials are preferred materials. Materials such as polycarbonate (PC) and polyethylene terephthalate (PET) are less preferable options on UVA emitting light sources due to material degradation, although are feasible for white light LED lamps. The polymer is preferably an ethylene/propylene co-polymer in particular a perfluorinated ethylene/propylene co-polymer, such as the most preferable material tetrafluoroethylene-hexafluoropropylene copolymer.

The fluoropolymer coating preferably has a refractive index of from 1.30 to 1.60 such as PVDF (1.443), PCTFE (1.435), ETFE (1.4), FEP (1.344), PFA (1.34), PTFE (1.356), THV (1.35), PC (1.586) and PET (1.575).

The particulate material is selected from light diffusive particles such as metal oxide particles, such as titanium dioxide, glass beads, white inorganic powder such as barium sulphate, magnesia or mixture thereof. The particulate material is preferably barium sulphate and is further preferably present to 0.5-5.0% w/w of the coating. The average particulate size of the particulate material is preferably from 3.0-30.0 μm, especially 0.7 μm. In an alternative embodiment, the average particulate size of the particulate material is <0.02 nm.

The particulate material preferably has a refractive index of from 1.00 to 2.30 such as titanium dioxide particles (refractive index 2.65), glass beads (refractive index 1.5 to 2.4), white inorganic powder-barium sulphate (refractive index 1.64), magnesia (refractive index 1.00 to 111 . . . 734@632.nm), titania (refractive index 1.55 to 2.3).

The light source is preferably an LED light source to offer energy efficiency and durability.

The thickness of the coating is preferably from 180.0-500.0 μm.

According to a second aspect of the invention, there is provided a coating for a lighting unit, the coating comprising a polymeric material formed of a fluorinated ethylene-propylene copolymer (FEP), having barium sulphate (BaSO₄) distributed therein, on the outer surface of the housing to diffuse light emitted into a uniformly distributed visual appearance.

The barium sulphate is preferably present in the coating to a level of from 0.5-5.0% w/w. The average particle size of the barium sulphate is preferably selected from the range of 3-30 μm, further preferably 0.7 μm. In an alternative embodiment, the average particulate size is <0.02 nm. The coating preferably has a thickness of from 180-500 μm, and further preferably from 200 μm-300 μm.

According to a third aspect of the invention there is provided a method of coating a housing of a lighting unit, the lighting unit having a light housing, the method comprising the steps of blending a fluorinated ethylene-propylene (FEP) co-polymer, preferably a perfluorinated ethylene-propylene (FEP) co-polymer with barium sulphate and applying the blended material to the surface of a light housing to provide a diffusive coating transparent to visible light and UV-A. The blended material is optionally provided as a film.

The blended material is alternatively optionally provided as a direct extrusion coating.

The blended material is alternatively provided as a heat shrink tubing.

According to a fourth aspect of the invention there is provided a single lighting unit coating, between 0.01 to 2.00 metres in length most preferably 0.20 to 1.90 metres is provided for direct extrusion, applied as a continuous coating in the manufacturing process then separated to lamp length for a service unit. For film and heat shrink tubing purposes, reels measure from 10 to 500 metres in overall length, most preferably 50 to 150 metres per reel. Bespoke cut lengths in the stated ranges above can also optionally be provided.

### BRIEF DESCRIPTION OF THE DRAWINGS

The invention is now described with reference to the accompanying drawings which show by way of example only, an embodiment of coating on a lighting tube. In the drawings:

FIG. 1 shows orthogonal side views of a first embodiment of LED lighting lamp which is uncoated as standard; and

FIG. 2 shows orthogonal side views of a second embodiment of a LED lighting lamp which is coated with the present invention of the polymeric diffusion material.

### DETAILED DESCRIPTION OF THE INVENTION

In traditional photoluminescent lights, such as those referred to conventionally as fluorescent lights, a low-pressure mixture of mercury and noble gas is excited energetically by means of electrons to produce light. Because of the nature of the transitions, at least some of this light is in the UV region which is not only not required for conventional white light purposes, but also potentially dangerous to any users in the vicinity of the light. In order to make the light safe for use in domestic and industrial environments, and to produce light in the visible wavelength range, the tubes of the lights are usually coated with one or more materials, either on the inside of the tube or on the outside: depending on the nature and function of the coating. The materials absorb the UV light and re-emit light of a visible wavelength. Moreover, the coating acts to emit in all directions so providing a diffuse light more comfortable for the user.

Similarly, coatings can be applied to lighting units such as light bulbs having an incandescent light element, to diffuse the light generated by a filament and to remove any residual UV light. More recently, the advent of commercially available LED light sources also utilises a layer of material such as a coating or film of material between the LED light source and the user. LEDs emit a narrow range of wavelengths and in order to convert this to a white light, the emitted light is passed through a layer of photoluminescent material. The present invention provides a coating which produces a diffused light for the surroundings, but allows the transmission of UV radiation, most preferably UV-A radiation. UV radiation is utilised for example in tanning beds where UV-B can enable people to tan and to produce Vitamin D naturally. As further, non-limiting, examples of uses to which UV-transmitting lighting units can be used, then use within the pest or insect control industry can be cited. The UV-light acts to attract insects which can then be caught within a suitable trap or eliminated, such as in the conventional UV-lights found in most food establishments. This enables increased protection for food crops. Additionally, UV-light is utilised in curing materials (polymerisation of a monomer to form a polymer) for example in inks, adhesives, coatings, and 3-D materials such as formed in dentistry. Control of the behaviour of pets and livestock such as reptiles and poultry can also be achieved through the use of UV-light.

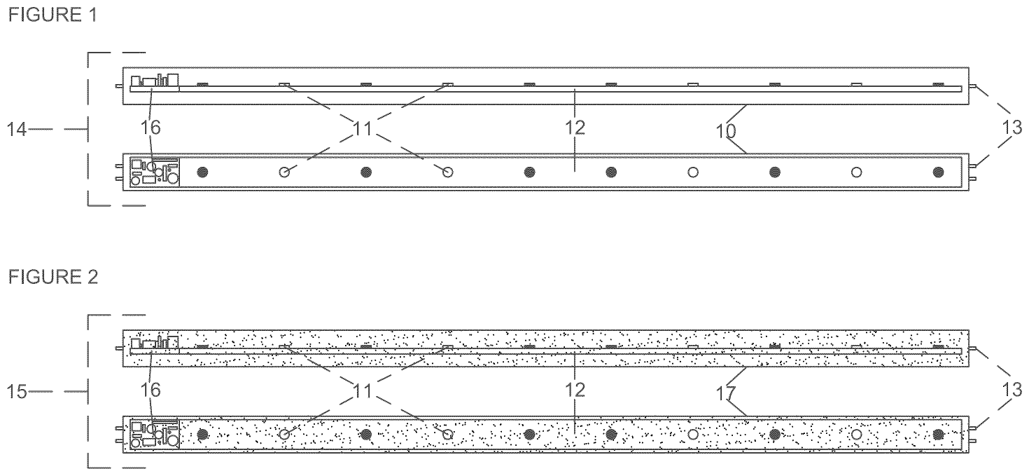

Referring to the FIGS. 1 and 2, these illustrate a lighting unit comprising a tube housing a plurality of LED light sources which in combination emit light across the visible and UV spectrum—including 315 to 400 nm (UV-A), 280-315 nm (UV-B) and 100-280 nm (UV-C)—with each LED emitting light of a tight spread of wavelengths. In-use, the diodes present or activated will be selected for the purpose to which the lighting unit is intended. The light housing is configured to allow the emission and transmission of UV light, unlike conventional lights. This brings with it, particular problems as in order to produce a diffused light outside the tube, a coating which is applied needs to be able to be more robust towards UV radiation and to resist degradation thereby.

In FIGS. 1 and 2, a generally tubular, linear LED lamp housing 10, of LED lights, generally referenced 14, 15, houses the LED light source elements (or LEDs) 11 as a linear array on a circuit board 12 allowing power to be supplied to the LEDs 11. Power is supplied to the circuit board 12 via the pins 13 and the driver 16 on the end of the tubes 14, 15 which power controls the illumination of the LEDs 11. The linear LED lamp housing 10 provides a sealed volume preventing air from entering the LEDs 11 and the driver 16 allowing a low-pressure environment to be maintained.

A coating material 17 is applied covering the outer surface of the linear LED lamp housing 10 or the like, which gives the linear LED lamp housing 10 an opaque visual appearance in comparison with the clear visual appearance of a standard uncoated lamp both in the power on and off mode, more so in the power on mode as light from the inside of the linear LED lamp is diffused. In FIG. 1 the linear LED lamp housing 10 is shown as a standard uncoated lamp for reference whilst in FIG. 2 the lamp has been shown fully coated across the entire outer cylindrical surface and trimmed flush with the end cap leaving the connection pins 13 exposed.

The coating as particularly contemplated in the present invention is a polymeric resin blended with a white particulate solid to aid in the diffusion of the light, without diminishing the transmissivity of the coating material towards visible and UV light. In its broadest aspect, the present invention contemplates a coating comprising a polymeric material formed of a fluorinated polymer. The polymeric material is preferably selected from a fluoropolymer coating such as polyvinylidene fluoride (PVDF), polychlorotrifluoroethylene (PCTFE), tetrafluoroethylene-ethylene copolymer (ETFE), tetrafluoroethylene-hexafluoropropylene copolymer (FEP), tetrafluoroethylene-perfluoroalkyl vinyl ether copolymer (PFA), polytetrafluoroethylene (PTFE), tetrafluoroethylene-hexafluoropropylene-vinylidene fluoride co-polymer (THV) and the like, and including mixtures thereof. Materials such as Polycarbonate (PC) and Polyethylene terephthalate (PET) are less preferable options on UVA emitting light sources due to material degradation, although are feasible for white light LED lamps. The most preferable material is tetrafluoroethylene-hexafluoropropylene copolymer (FEP).

The fluoropolymer coating preferably has a refractive index of between 1.30 and 1.60 such as PVDF (1.443), PCTFE (1.435), ETFE (1.4), FEP (1.344), PFA (1.34), PTFE (1.356), THV (1.35), PC (1.586) and PET (1.575).

The copolymer is blended with uniformly distributed light diffusive particles such as metal oxide particles, such as titanium dioxide, glass beads, white inorganic powder such as barium sulphate, magnesia. The particulate material is preferably present to 0.5-5.0% by weight of the overall mixture. The particle size of the particulate material is chosen to suit the application but can be within the range of 3-30 μm and especially ˜0.7 μm. The preferred particulate material is barium sulphate (barites and some synthetic grades) which can have a particulate size range of 3-30 μm and especially ˜0.7 μm (blanc-fixe). For certain uses the particulate material has a particle size <0.02 nm. The amount of barium sulphate is chosen to suit the particular use contemplated. The preformed polymer is fed into an extruder where the extrusion process softens and blends the polymer with the barium sulphate together to form a suitable coating material.

The particulate material preferably has a refractive index of between 1.00 and 2.30 such as titanium dioxide particles (refractive index 2.65), glass beads (refractive index 1.5 to 2.4), white inorganic powder-barium sulphate (refractive index 1.64), magnesia (refractive index 1.00 to 111 . . . 734@632.nm), titania (refractive index 1.55 to 2.3).

The material thus produced can be utilised in a number of ways. The mix density of the diffusive coating is governed by the maximum allowable UV transmittance block and will not exceed ≥10% of original output off UV light source. >than 10% transmittance block will fail required output levels. First, the material can be formed into a tube which functions as the housing for the light sources. The thickness of the material can range from 180-500 μm, preferably from 200 μm-300 μm with a tolerance of +/-−30 μm. This tube can be applied directly extruded onto a lamp or as an independent tube where a secondary expansion process is performed to create heat shrink tubing.

Second, the material can be formed into a film which is applied to the surface of the housing, the film having a thickness within the same range of 180-500 μm. Application as a film or sleeve allows for a simpler application process as it is applied at end of process which allows a more efficient assembly of the base lamp with fewer rejects or defects (no scratching of internal diffusion when inserting LED components into glass envelope). External coating helps to protect against foreign body ingress (contaminants such as water, dust and grease) into the glass envelope causing short life cycle/early failure.

Third, the mixture formed can be extruded as a melt to form a tube or film of material, applied directly to the flat or tubular cylindrical surface of the light housing. Optimal material thickness range (for example for pest control/flying insect control), for a material having 2.5% barium sulphate mix is 180 to 210 μm (micron) to maximise UV transmission while maintaining “spotting” reduction.

1. A lighting unit, the lighting unit comprising a light source retained within a housing, the housing having an outer coating comprising a polymeric coating material, the polymeric coating material having distributed therein a particulate material to diffuse light emitted by the light source.

2. A lighting unit according to claim 1, wherein the polymeric coating material is selected from a fluoropolymer.

3. A lighting unit according to claim 2, wherein the polymeric coating material is selected from: polyvinylidene fluoride (PVDF), polychlorotrifluoroethylene (PCTFE), tetrafluoroethylene-ethylene copolymer (ETFE), tetrafluoroethylene-hexafluoropropylene copolymer (FEP), tetrafluoroethylene-perfluoroalkyl vinyl ether copolymer (PFA), polytetrafluoroethylene (PTFE), tetrafluoroethylene-hexafluoropropylene-vinylidene fluoride co-polymer (THV) or mixtures thereof.

4. A lighting unit according to claim 2, wherein the polymeric coating material is a perfluorinated material.

5. A lighting unit according to claim 2, wherein the polymeric material is an ethylene/propylene co-polymer.

6. A lighting unit according to claim 5, wherein the polymeric coating material is tetrafluoroethylene-hexafluoropropylene copolymer.

7. A lighting unit according to claim 1, wherein the polymeric coating material is a polycarbonate, or a polyethylene terephthalate.

8. A lighting unit according to claim 2, wherein the fluoropolymer coating has a refractive index of from 1.30 and 1.60.

9. A lighting unit according to claim 1, wherein the particulate material is a metal oxide.

10. A lighting unit according to claim 9, wherein the particulate material is selected from: titanium dioxide, glass beads, barium sulphate, magnesia, or other white inorganic powder.

11. A lighting unit according to claim 10, wherein the particulate material is barium sulphate.

12. A lighting unit according to claim 11, wherein the barium sulphate is present to 0.5-5.0% (w/w) of the coating.

13. A lighting unit according to claim 1, wherein the average particulate size of the particulate material is from 3.0 μm-30.0 μm.

14. A lighting unit according to claim 13, wherein the average particulate size of the particulate material is 0.7 μm.

15. A lighting unit according to claim 1, wherein the average particulate size of the particulate material is <0.02 nm.

16. A lighting unit according to claim 1, wherein the particulate material has a refractive index of between 1.00 and 2.30.

17. A lighting unit according to claim 1, wherein the light source is a light emitting diode (LED).

18. A lighting unit according claim 1, wherein the thickness of the polymeric coating material is preferably from 180.0-500.0 μm.

19. A coating for a lighting unit, the coating comprising a polymeric material formed of a fluorinated ethylene-propylene copolymer (FEP), having particulate barium sulphate (BaSO₄) distributed therein, on the outer surface of the housing, to diffuse light emitted into a uniformly distributed visual appearance.

20. A coating for a lighting unit according to claim 19, wherein the particulate barium sulphate is present in the coating to a level of from 0.5-5.0 % (w/w).

21. A coating for a lighting unit according to claim 19, wherein the particle size of the particulate barium sulphate is selected from the range of 3-30 μm.

22. A coating for a lighting unit according to claim 21, wherein the average particulate size of the particulate barium sulphate (BaSO₄)is 0.7 μm.

23. A coating for a lighting unit according to claim 19, wherein the average particulate barium sulphate (BaSO₄) size is <0.02 nm.

24. A coating for a lighting unit according to claim 19, wherein the coating has a thickness of from 180-500 μm.

25. A coating for a lighting unit according to claim 24, wherein the coating has a thickness of 200 μm-300 μm.

26. A method of coating a housing of a lighting unit, the lighting unit having a light housing, the method comprising the steps of blending a fluorinated ethylene-propylene (FEP) co-polymer with particulate barium sulphate and applying the blended material to the surface of the light housing to provide a diffusive coating transparent to visible light and UV-A.

27. A method of coating a lighting unit according to claim 26, wherein the co-polymer is a perfluorinated ethylene-propylene (FEP) co-polymer.

28. A method of coating a lighting unit according to claim 26, wherein the blended material is provided as a film.

29. A method of coating a lighting unit according to claim 26, wherein the blended material is provided as a direct extrusion coating.

30. A method of coating a lighting unit according to claim 26, wherein the blended material is provided as a heat shrink tubing.

31. A single lighting unit coating, from 0.01 to 2.00 metres in length is provided for direct extrusion, applied as a continuous coating in the manufacturing process then separated to lamp length for a service unit.

32. A single lighting unit coating according to claim 31, wherein the coating is from 0.20 to 1.90 metres in length.
